(19) United States
(12) Patent Application Publication
(10) Pub. No.: US 2007/0034509 A1
(43) Pub. Date: Feb. 15, 2007

(54) Magnetic filter for physical vapor deposition equipment

(76) Inventor: Ching-Ching Chen, Wugu Township (TW)

Correspondence Address: HDSL, 4331 STEVENS BATTLE LANE, FAIRFAX, VA, 22033, US

(21) Appl. No.: 11/202,172

(22) Filed: Aug. 12, 2005

(51) Int. Cl. C23C 14/00

(52) U.S. Cl. 204/298.16

(57) ABSTRACT

A magnetic filter for physical vapor deposition equipment is disposed at the exit of a sputtering target. The magnetic filter includes a pipe and a magnetic field generator. The pipe includes an entrance end, an exit end, and at least a crooked portion formed between the entrance end and the exit end. The entrance end is connected to the exit of the sputtering target. The particle size of the metallic ions sputtered from the sputtering target that can pass the pipe is controlled by the intensity of the magnetic field generated from the magnetic field generator. In this manner, the nanometer particles and the micrometer particles sputtered from the sputtering target can be separated. Only the nanometer particles can pass through the pipe and be coated on the sample surface. This will enhance the structural strength and mechanical properties of the coated film, and extend the life expectancy of the coated sample.

### BACKGROUND OF THE INVENTION

The present invention relates generally to physical vapor deposition equipment, and more particularly to a magnetic filter for the physical vapor deposition equipment that can separate the micrometer particles and the nanometer particles sputtered from the sputtering target.

Currently, the physical vapor deposition (PVD) has become a common technology for performing surface processing on ornaments, utensils, knifes, tools, molds and semiconductors. The PVD technology can apply a nanometer ionic coating to the samples, thereby increasing the heat and erosion resistance, the surface hardness, and the life expectancy. However, it is important in the art to provide a filter for the PVD equipment that can separate the micrometer particles from the nanometer particles, such that only the nanometer particles are coated onto the sample surface, so as to extend the mechanical properties and the life expectancy of the sample.

One conventional filter for physical vapor deposition equipment is disclosed in Taiwanese patent publication no. 512181. The filter is a filtering web that is disposed between the sputtering target and the sample. The filtering web is composed of vertically and horizontally interwoven metallic wires. A plurality of web holes are formed between the vertically and horizontally interwoven metallic wires. The filtering web is surrounded with insulating materials, for example, a ceramic material, such that the filtering web does not form an electrode, thereby filtering the metallic ions of different particle sizes. The filtered metallic particles can then be coated onto the sample surface.

However, the conventional filter for the physical vapor deposition equipment includes the following drawbacks. Since the web holes of the filtering web are formed from the vertically and horizontally interwoven wires, some metallic ions sputtered from the sputtering target will accumulate on the wires. On the other hand, some metallic particles of larger sizes will be blocking the web holes, thereby hindering the separation of micrometer particles and nanometer particles. In addition, such a conventional filter can not guide the motion of the sputtered ions. The motion of the micrometer particles of larger mass and lower velocity will be interfered with the motion of the nanometer particles. This will lower the performance of the physical vapor deposition equipment.

Accordingly, the inventor of the present invention realized the drawbacks in the conventional art, and developed the present invention that can overcome the drawbacks described above.

### BRIEF SUMMARY OF THE INVENTION

The present invention is to provide a magnetic filter for physical vapor deposition equipment. Since the moving path of the nanometer particles is different from that of the micrometer particles, the nanometer particles are separated from the micrometer particles. The micrometer particles remain in the pipe, while the nanometer particles are pushed through the pipe via a magnetic field generator and are coated on the sample surface. In this manner, both the structural strength and the coating adhesion of the coated film are enhanced.

In order to achieve the objectives, the magnetic filter for physical vapor deposition equipment of the present invention includes a pipe, and a magnetic field generator. The pipe includes an entrance end, an exit end, and at least a crooked portion formed between the entrance end and the exit end. The entrance end is connected to the exit of the sputtering target. The particle size of the metallic ions sputtered from the sputtering target that can pass the pipe is controlled by the intensity of the magnetic field generated from the magnetic field generator. Only the nanometer particles can pass through the pipe and be coated on the sample surface.

### BRIEF DESCRIPTION OF THE DRAWINGS

FIG. 1 illustrates a magnetic filter for physical vapor deposition equipment, in accordance with one embodiment of the present invention.

FIG. 2 illustrates the usage of the magnetic filter for physical vapor deposition equipment, in accordance with one embodiment of the present invention.

FIG. 3 illustrates an enlarged view of the magnetic filter and the sputtering target, as shown in FIG. 2.

FIG. 4 is a sectional view illustrating the magnetic filter and the sputtering target, as shown in FIG. 2.

FIG. 5 is a sectional view illustrating the pipe and the sputtering target, in accordance with another embodiment of the present invention.

FIG. 6 is a sectional view illustrating the pipe and the sputtering target, in accordance with yet another embodiment of the present invention.

FIG. 7 is a sectional view illustrating the pipe and the sputtering target, in accordance with still another embodiment of the present invention.

### DETAILED DESCRIPTION OF THE INVENTION

In order to better understanding the features and technical contents of the present invention, the present invention is hereinafter described in detail by incorporating with the accompanying drawings. However, the accompanying drawings are only for the convenience of illustration and description, no limitation is intended thereto.

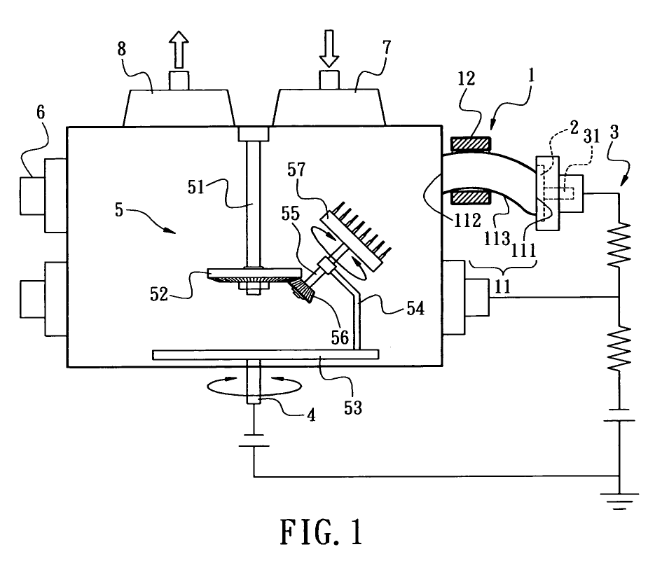

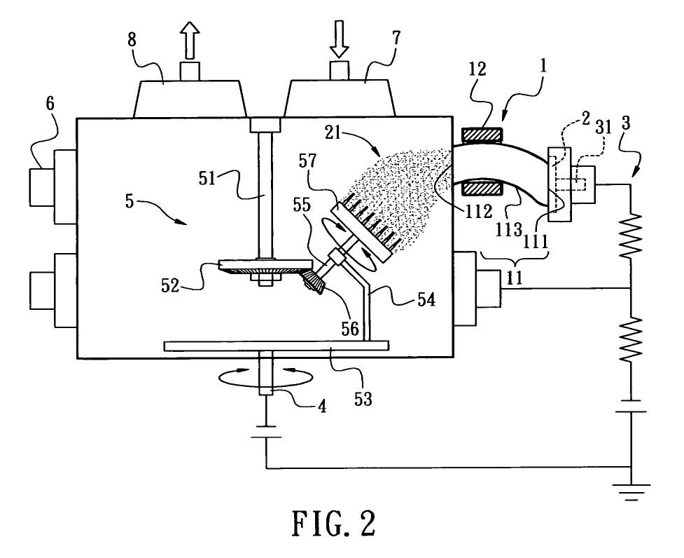

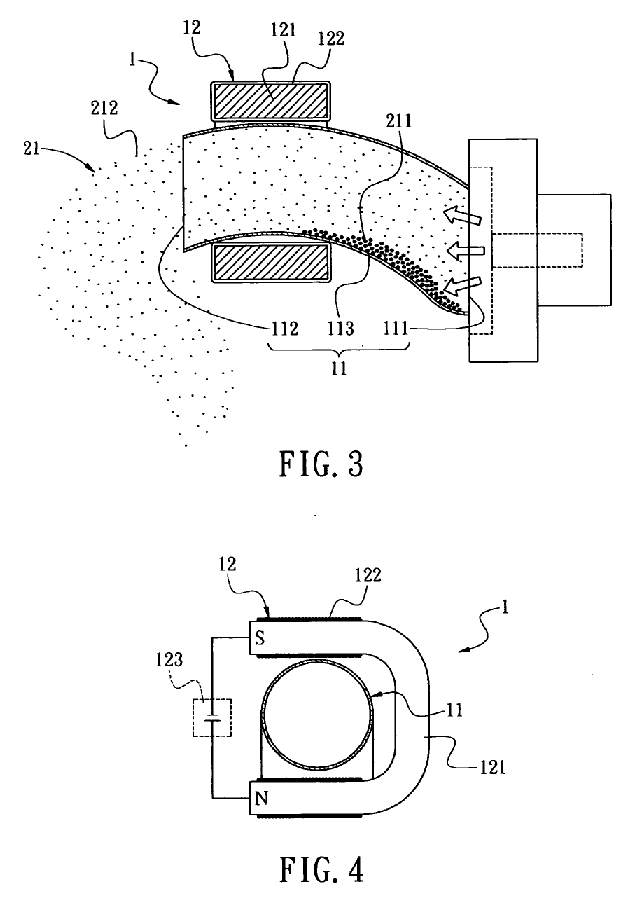

Referring to FIG. 1, FIG. 2, FIG. 3 and FIG. 4, a magnetic filter for physical vapor deposition equipment is illustrated. The magnetic filter of the present invention includes a pipe 11 and a magnetic field generator 12 surrounding the pipe 11.

The pipe 11 is made of metallic material, which includes an entrance end 111, an exit end 112, and at least a crooked portion 113. The cross section of the pipe 11 can be of a circular shape, a rectangular shape, an elliptic shape, or any other geometrical shapes. In this particular embodiment, the cross section of the pipe 11 is of a circular shape.

The magnetic field generator 12 is an electromagnet or other magnetic element capable of tuning the intensity of the generated magnetic field. In this particular embodiment, the magnetic field generator 12 is an electromagnet (as shown in FIG. 4). The magnetic field generator 12 is composed of a U-shape magnet 121, two conducting coils 122 surrounding the poles (North and South poles) of the magnet 121, and a power supply 123 electrically connected to each conducting coil 122. The output voltage and current of the power supply 123 is adjustable, such that the magnetic field generator 12 can generate magnetic fields of different intensity.

The vacuum chamber of the physical vapor deposition equipment is first evacuated to a predetermined vacuum degree by using a pump 8. The rotation plate 53 then starts to perform a rotational motion, so as to rotate the mutually engaged small bevel gear 56 and large bevel gear 52. The insertion base 57 having a sample inserted thereon will then perform an inclined rotational motion. The sample is heated to a higher temperature. The sample surface is also cleaned via the sputtered ions from the ionic device 6. The metallic ions 21 are sputtered from the sputtering target 2 by using an electric arc gun 31, thereby forming trajectories of different arc radius. Since the micrometer particles 211 comprise larger mass, which will travel along an arc path of larger radius (almost linear path), they will not pass through the pipe 11 and will remain in the crooked portion 112. On the other hand, since the nanometer particles 212 comprise smaller mass, which will travel along an arc path of smaller radius (a nonlinear path), they will pass through the pipe 11 due to the magnetic force produced from the magnetic field generator 12. The nanometer particles 212 can be homogeneously distribute and adhered onto the sample surface. Thus, the structural strength of the coating and the adhesion strength with the sample are both enhanced. Finally, some nitrogen and carbon containing air is guided through the entrance 7, and a cooling process is performed, thereby completing the coating process.

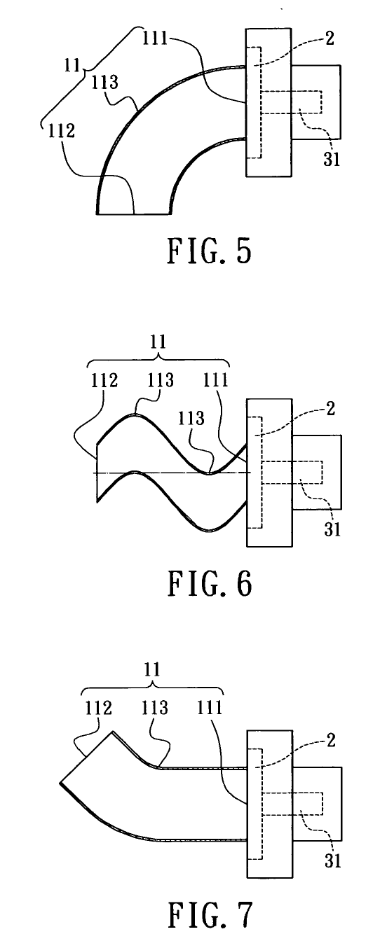

Referring to FIG. 5 and FIG. 6, section views of the magnetic filter for physical vapor deposition equipment, in accordance with another and yet another embodiments of the present invention, are illustrated. The entrance end 111 and the exit end 112 of the pipe form an angle of 90 degrees (as shown in FIG. 5), so as to filter out metallic ions 21 of different particle sizes. In addition, the pipe 11 can be composed of crooked portions 113 of different bending direction. As shown in FIG. 6, the tangent lines of the protrusive inner walls of the two crooked portions 113 are aligned to the same horizontal line, while the surface of the entrance end 111 and the surface of the exit end 112 are parallel to each other. In this manner, the pipe 11 can produce multiple filtering effect to the metallic ions 21 sputtered from the sputtering target 2.

Referring to FIG. 7, a sectional view of the pipe, in accordance with yet another embodiment of the present invention, is illustrated. The pipe 11 is horizontally extended from the entrance end 111, and then folded upward, such that the position of the exit end 112 is higher than that of the entrance end 111. The size of the metallic ions 21 that pass through the pipe 11 will then be further refined.

The magnetic filter for physical vapor deposition equipment of the present invention not only can improve the drawbacks in the conventional art, it is also advantageous in the following aspects. Since the pipe is crooked, the nanometer particles sputtered from the sputtering target are well separated from the micrometer particles. The micrometer particles are remained in the pipe, while the nanometer particles pass through the pipe and are distributed and adhered on the sample surface. Thus, the structural strength and the adhesion of the coated film are both enhanced. Furthermore, when a different voltage or current is applied to the magnetic field generator, the size of the metallic ion particles that can pass through the pipe is changed correspondingly. In addition, the nanometer particles that passed through the pipe are moving along the same direction. This enhances the simplicity of operation and convenience of usage. Moreover, by using the magnetic filter of the present invention, the coated film on the sample surface will become glossier, while the hardness, the adhesion and the density of the coated film will become higher.

In summary, the magnetic filter for physical vapor deposition equipment of the present invention indeed satisfies the patentability requirements of the patent law, a grant of letters patent therefor is thus respectfully requested.

Since, any person having ordinary skill in the art may readily find various equivalent alterations or modifications in light of the features as disclosed above, it is appreciated that the scope of the present invention is defined in the following claims. Therefore, all such equivalent alterations or modifications without departing from the subject matter as set forth in the following claims is considered within the spirit and scope of the present invention.

What is claimed is:

1. A magnetic filter for physical vapor deposition equipment having a sputtering target, the magnetic filter comprising:
a pipe including an entrance end, an exit end, and at least a crooked portion formed between the entrance end and the exit end, the entrance end being connected to the exit of the sputtering target; and
a magnetic field generator disposed around the exterior of the pipe, whereby the particle size of the metallic ions sputtered from the sputtering target that can pass the pipe is controlled by the intensity of the magnetic field generated from the magnetic field generator.

2. The magnetic filter as recited in claim 1, wherein a cross section of the pipe is one of a circular shape, a rectangular shape, and an elliptic shape.

3. The magnetic filter as recited in claim 1, wherein an angle formed between the entrance end and the exit end is 90 degrees.

4. The magnetic filter as recited in claim 1, wherein tangent lines of protrusive inner walls of the crooked portions are aligned to the same horizontal line.

5. The magnetic filter as recited in claim 1, wherein the magnetic field generator comprises an electromagnet.

6. The magnetic filter as recited in claim 5, wherein the electromagnet comprises a magnet, two conducting coils surrounding the two poles of the magnet, and a power supply electrically connected to the conducting coils.
